(19) United States
(12) Patent Application Publication
(10) Pub. No.: US 2024/0194732 A1
(43) Pub. Date: Jun. 13, 2024

(54) CHEMICAL MECHANICAL POLISHING OF CARBON HARD MASK

(71) Applicant: Intel Corporation, Santa Clara, CA (US)

(72) Inventors: Matthew J. Prince, Portland, OR (US); Amitesh Shrivastava, Chandler, AZ (US); Walid M. Hafez, Portland, OR (US); Anurag A. Jain, Portland, OR (US); Gary Ding, Portland, OR (US); Sharath Hegde, Portland, OR (US); Caitlin M. Kilroy, Hillsboro, OR (US); Inki Kim, Portland, OR (US)

(73) Assignee: Intel Corporation, Santa Clara, CA (US)

(21) Appl. No.: 18/077,658

(22) Filed: Dec. 8, 2022

(51) Int. Cl. H01L 29/06; H01L 21/033; H01L 29/08; H01L 29/66

(52) U.S. Cl. CPC H01L 29/0673; H01L 21/0332; H01L 21/0337; H01L 29/0843; H01L 29/66439

(57) ABSTRACT

Techniques are provided herein to use a chemical mechanical polishing (CMP) process to polish carbon hard mask (CHM) for a variety of useful semiconductor fabrication applications. In one example, a CMP process that uses a silica-based slurry is used to polish CHM formed over gate trenches of different widths, such that the CHM can recess to substantially the same height within the gate trenches of different widths. In another example, CHM may be deposited over groups of fins or a backbone structure and polished using a CMP process with a silica-based slurry to ensure a planar top surface of CHM over the groups of fins or backbone structure.

### FIELD OF THE DISCLOSURE

The present disclosure relates to integrated circuits, and more particularly, to chemical mechanical polishing processes during the fabrication of integrated circuits.

### BACKGROUND

As integrated circuits continue to scale downward in size, a number of challenges arise. For instance, reducing the size of memory and logic cells is becoming increasingly more difficult. Different transistor architectures that maximize available semiconductor surfaces to form active channels have been contemplated, including nanosheet (e.g., gate-all-around) and forksheet architectures. Such transistor devices may have different sizes or be grouped together with different densities on the same chip or across the same wafer. These variations in device size or density can cause problems during batch processing across all of the devices. Accordingly, there remain a number of non-trivial challenges with respect to forming certain transistor structures.

### BRIEF DESCRIPTION OF THE DRAWINGS

FIG. 1 is a cross-section view of a pair of semiconductor devices that illustrates a first semiconductor device and a second semiconductor with a wider gate trench, where each semiconductor device includes a work function layer that extends to substantially the same height within the respective gate trenches, in accordance with an embodiment of the present disclosure.

FIGS. 2A-2L are cross-section views that illustrate various stages in an example process for forming semiconductor devices with work function layers that extend to substantially the same height within the respective gate trenches of the semiconductor devices, in accordance with some embodiments of the present disclosure.

FIGS. 3A-3F are cross-section views that illustrate various stages in an example process for removing certain fins from groups of fins to facilitate different device densities, in accordance with some embodiments of the present disclosure.

FIG. 4 illustrates a cross-section view of a chip package containing one or more semiconductor dies, in accordance with some embodiments of the present disclosure.

FIG. 5 is a flowchart of a fabrication process for semiconductor devices with diverse-width gate structures having work function layers that extend to substantially the same height within the respective gate trenches of the semiconductor devices, in accordance with an embodiment of the present disclosure.

FIG. 6 is a flowchart of a fabrication process for removing certain fins from groups of fins to facilitate different fin densities, in accordance with some embodiments of the present disclosure.

FIG. 7 illustrates a computing system including one or more integrated circuits, as variously described herein, in accordance with an embodiment of the present disclosure.

Although the following Detailed Description will proceed with reference being made to illustrative embodiments, many alternatives, modifications, and variations thereof will be apparent in light of this disclosure. As will be further appreciated, the figures are not necessarily drawn to scale or intended to limit the present disclosure to the specific configurations shown. For instance, while some figures generally indicate perfectly straight lines, right angles, and smooth surfaces, an actual implementation of an integrated circuit structure may have less than perfect straight lines, right angles (e.g., such as tapered sidewalls and rounded corners), and some features may have surface topology or otherwise be non-smooth, given real world limitations of the processing equipment and techniques used.

### DETAILED DESCRIPTION

Techniques are provided herein to use a chemical mechanical polishing (CMP) process to polish carbon hard mask (CHM) for a variety of useful semiconductor fabrication applications. The techniques can be used in any number of integrated circuit applications and are particularly useful with respect to device layer transistors, such as finFETs or gate-all-around transistors (e.g., ribbonFETs and nanowire FETs). In one example, a first semiconductor device includes a first gate structure around or otherwise on a first semiconductor region and a second semiconductor device includes a second gate structure around or on a second semiconductor region. The second gate structure is wider than the first gate structure. When forming the gate structures within respective gate trenches, CHM is deposited and recessed within each of the gate trenches to pattern the height of a work function layer in each gate trench. Prior to the CHM recessing, a CMP process is used to polish the CHM to eliminate or otherwise reduce height differential in the CHM deposition, such that the CHM can subsequently recess to substantially the same height within the first gate trench and within the wider second gate trench. In another example, CHM may be deposited over groups of fins (e.g., for forming finFETs or ribbonFETs) or spacers (e.g., for forming a backbone grating) and polished using a CMP process to ensure a planar top surface of CHM over the groups of fins. The CMP process may be carried out, for example, with a silica-based slurry, so as to better tune the CMP process for CHM. Numerous variations and embodiments will be apparent in light of this disclosure.

### General Overview

As previously noted above, there remain a number of non-trivial challenges with respect to integrated circuit fabrication. In more detail, as devices become smaller and more densely packed, many structures become more challenging to fabricate as critical dimensions (CD) of the structures push the limits of current fabrication technology. Certain devices may have different dimensions, such as different gate widths or different device densities on the chip, which can present challenges when trying to deposit certain materials over all of the devices. The material may not deposit evenly over such devices with different geometries and/or densities. For example, a carbon hard mask (CHM) thickness varies within a given die because CHM fill is dependent on trench volume (e.g., wider trenches tend to fill slower than narrower trenches, given the flowable nature of CHM spun or otherwise deposited onto the die). Exacerbating this situation is that using a standard CHM etch-back process as currently done to set-up the mask for the subsequent feature etch will uniformly etch the CHM and thus preserve the height variation caused by trench volume differences. This height variation in turn causes the features being formed to also have varying height. For instance, a work function layer formed in a narrow gate trench will have a height that is taller than a work function layer formed in a wider gate trench. Likewise, fins or spacer structures having a higher density or pitch will have a height that is taller than fins or spacer structures having a lower density or pitch. More generally, for a given die, any set of like-features having trench volume diversity and that are formed using a standard CHM etch-back process will be susceptible to feature height variation. Such feature height variation can lead to transistor performance and yield variation.

Thus, and in accordance with an embodiment of the present disclosure, techniques are provided herein to alleviate the problems noted above when using CHM to form various features of semiconductor devices. CHM, and other similar sacrificial materials, are very useful as a sacrificial masking material because they can be deposited at low temperatures and can be removed via an ashing process that does not damage surrounding structures. Although CHM will be used throughout this disclosure as an example masking material, any similar sacrificial masking material that is susceptible to height variation based on trench volume diversity and that can be removed without damaging the surrounding structures can be used in its place. According to some embodiments, a CMP process that uses a silica-based slurry is used to polish CHM to provide more robust use of the CHM over devices with different geometries and/or device densities. Standard CMP processes use an alumina-based slurry, which may provide insufficient selectivity or otherwise be inadequate when attempting to polish CHM, so using a silica-based slurry as described herein facilitates use of CMP to polish CHM. In one example, CHM is deposited into gate trenches of different widths and recessed back to remove portions of work function layers along the upper sidewalls of the gate trenches. By using the techniques described herein, the CHM may be recessed to substantially the same height within the gate trenches of different widths, which yields work function layers that extend to a substantially same height (e.g., within 2 nm) within the gate trenches of different widths. Having the same heights of work function layers across different devices provides more consistent performance and yield metrics. In another example, CHM is deposited across fins (e.g., of a logic section) or spacers (e.g., of a backbone section) having different densities on a same substrate. Density refers to the spacing between adjacent semiconductor devices or repeating features, such as fins or spacers. By using the CMP process disclosed herein, any variation in the height of the CHM across the fins having different device densities can be leveled out to provide more accurate downstream processing of the various devices. So, the resulting fins or spacers all have a height within an acceptable tolerance (e.g., +/−1 nm of a target height, or within 2 nm of each other).

According to an embodiment, an integrated circuit includes a first semiconductor device having a first semiconductor region extending in a first direction between a first source region and a first drain region, and a first gate structure extending in a second direction over the first semiconductor region. The first gate structure has a first width along the first direction. The integrated circuit also includes a second semiconductor device having a second semiconductor region extending in the first direction between a second source region and a second drain region, and a second gate structure extending in the second direction over the second semiconductor region. The second gate structure has a second width along the first direction, where the second width is greater than the first width. The first gate structure includes a first conductive layer and a first conductive fill on the first conductive layer. The second gate structure includes a second conductive layer and a second conductive fill on the second conductive layer. The first conductive layer extends above the first semiconductor region to a first height and the second conductive layer extends above the second semiconductor region to a second height that is within 2 nm of the first height.

According to another embodiment, a chip package includes one or more dies. At least one of the one or more dies includes a first semiconductor device having a first semiconductor region extending in a first direction between a first source region and a first drain region, and a first gate structure extending in a second direction over the first semiconductor region. The first gate structure has a first width along the first direction. The at least one of the one or more dies also includes a second semiconductor device having a second semiconductor region extending in the first direction between a second source region and a second drain region, and a second gate structure extending in the second direction over the second semiconductor region. The second gate structure has a second width along the first direction, where the second width is greater than the first width. The first gate structure includes a first conductive layer and a first conductive fill on the first conductive layer. The second gate structure includes a second conductive layer and a second conductive fill on the second conductive layer. The first conductive layer extends above the first semiconductor region to a first height and the second conductive layer extends above the second semiconductor region to a second height that is substantially the same (e.g., within 2 nm) as the first height.

According to another embodiment, a method of forming an integrated circuit includes forming a first fin comprising first semiconductor material, the first fin extending above a substrate and extending in a first direction; forming a second fin comprising second semiconductor material, the second fin extending above a substrate and extending in the first direction; forming a first sacrificial layer extending over the first semiconductor material in a second direction different from the first direction, the first sacrificial layer having a first width in the first direction; forming first spacer structures on sidewalls of the first sacrificial layer; forming a second sacrificial layer extending over the second semiconductor material in the second direction, the second sacrificial layer having a second width in the first direction that is greater than the first width; forming second spacer structures on sidewalls of the second sacrificial layer; removing both the first sacrificial layer and the second sacrificial layer to reveal a first trench having the first width between the first spacer structures and a second trench having the second width between the second spacer structures; forming a first conductive layer over the first semiconductor material and over sidewalls of the first spacer structures within the first trench; forming a second conductive layer over the second semiconductor material and over sidewalls of the second spacer structures within the second trench; forming a sacrificial material within the first trench and within the second trench over the first conductive layer and the second conductive layer; polishing a top surface of the sacrificial material using chemical mechanical polishing (CMP); recessing the sacrificial material within each of the first trench and the second trench, such that a recessed portion of the sacrificial material within the first trench has substantially the same height above the first semiconductor region as a recessed portion of the sacrificial material within the second trench above the second semiconductor region; and removing an exposed portion of the first conductive layer above the recessed portion of the sacrificial material within the first trench, and removing an exposed portion of the second conductive layer above the recessed portion of the sacrificial material within the second trench.

According to another embodiment, a method of forming an integrated circuit includes forming a first group of fins comprising semiconductor material, the first group of fins extending above a substrate and extending parallel to each other in a first direction, the first group of fins having a first fin density; forming a second group of fins comprising semiconductor material, the second group of fins extending above the substrate and extending parallel to each other in the first direction, the second group of fins having a second fin density lower than the first fin density; forming a sacrificial material over the first group of fins and the second group of fins; polishing a top surface of the sacrificial material using chemical mechanical polishing (CMP) until a top surface of the first group of fins and the second group of fins is exposed; and forming a layer of the sacrificial material on the polished top surface of the sacrificial material. A similar methodology can be used to form other spaced features, such as those features formed using a spacer-based patterning process. For example, a dielectric or conductive backbone structure having first and second groups of dielectric plugs or conductive lines, with the first group of features having a first spacing, and the second group of features having a second spacing, the second spacing being wider than the first spacing.

The techniques can be used with any type of non-planar transistors, but are especially useful for nanowire and nanoribbon transistors (sometimes called GAA transistors or forksheet transistors), to name a few examples. The source and drain regions can be, for example, doped portions of a given fin or substrate, or epitaxial regions that are deposited during an etch-and-replace source/drain forming process. The dopant-type in the source and drain regions will depend on the polarity of the corresponding transistor. The gate structure can be implemented with a gate-first process or a gate-last process (sometimes called a replacement metal gate, or RMG, process). Any number of semiconductor materials can be used in forming the transistors, such as group IV materials (e.g., silicon, germanium, silicon germanium) or group III-V materials (e.g., gallium arsenide, indium gallium arsenide).

Use of the techniques and structures provided herein may be detectable using tools such as electron microscopy including scanning/transmission electron microscopy (SEM/TEM), scanning transmission electron microscopy (STEM), nano-beam electron diffraction (NBD or NBED), and reflection electron microscopy (REM); composition mapping; x-ray crystallography or diffraction (XRD); energy-dispersive x-ray spectroscopy (EDX); secondary ion mass spectrometry (SIMS); time-of-flight SIMS (ToF-SIMS); atom probe imaging or tomography; local electrode atom probe (LEAP) techniques; 3D tomography; or high resolution physical or chemical analysis, to name a few suitable example analytical tools. For instance, in some example embodiments, such tools may indicate that the heights of work function layers within gate trenches of different widths extend substantially the same amount (e.g., within 2 nm of one another) above the top of the semiconductor regions in the gate trenches.

It should be readily understood that the meaning of “above” and “over” in the present disclosure should be interpreted in the broadest manner such that “above” and “over” not only mean “directly on” something but also include the meaning of over something with an intermediate feature or a layer therebetween. As used herein, the term “backside” generally refers to the area beneath one or more semiconductor devices (below the device layer) either within the device substrate or in the region of the device substrate (in the case where the bulk of the device substrate has been removed). Note that the backside may become a frontside, and vice-versa, if a given structure is flipped. To this end, and as will be appreciated, the use of terms like “above” “below” “beneath” “upper” “lower” “top” and “bottom” are used to facilitate discussion and are not intended to implicate a rigid structure or fixed orientation; rather such terms merely indicate spatial relationships when the structure is in a given orientation.

As used herein, the term “layer” refers to a material portion including a region with a thickness. A monolayer is a layer that consists of a single layer of atoms of a given material. A layer can extend over the entirety of an underlying or overlying structure, or may have an extent less than the extent of an underlying or overlying structure. Further, a layer can be a region of a homogeneous or inhomogeneous continuous structure, with the layer having a thickness less than the thickness of the continuous structure. For example, a layer can be located between any pair of horizontal planes between, or at, a top surface and a bottom surface of the continuous structure. A layer can extend horizontally, vertically, and/or along a tapered surface. A layer can be conformal to a given surface (whether flat or curvilinear) with a relatively uniform thickness across the entire layer.

Materials that are “compositionally different” or “compositionally distinct” as used herein refers to two materials that have different chemical compositions. This compositional difference may be, for instance, by virtue of an element that is in one material but not the other (e.g., SiGe is compositionally different than silicon), or by way of one material having all the same elements as a second material but at least one of those elements is intentionally provided at a different concentration in one material relative to the other material (e.g., SiGe having 70 atomic percent germanium is compositionally different than from SiGe having 25 atomic percent germanium). In addition to such chemical composition diversity, the materials may also have distinct dopants (e.g., gallium and magnesium) or the same dopants but at differing concentrations. In still other embodiments, compositionally distinct materials may further refer to two materials that have different crystallographic orientations. For instance, (110) silicon is compositionally distinct or different from (100) silicon. Creating a stack of different orientations could be accomplished, for instance, with blanket wafer layer transfer. If two materials are elementally distinct or different, then one of the material has an element that is not in the other material.

### Architecture

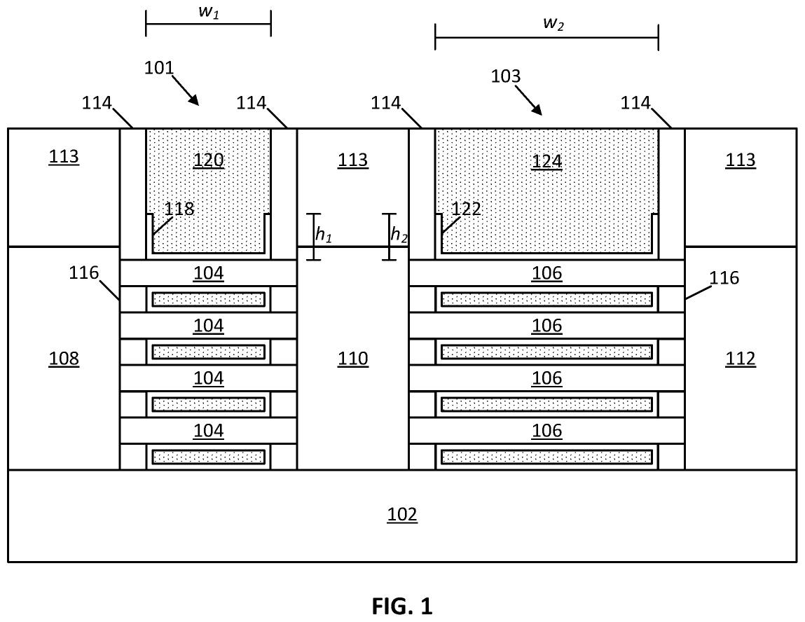

FIG. 1 is a cross-sectional view taken across a first semiconductor device 101 and a second semiconductor device 103, according to an embodiment of the present disclosure. Each of first and second semiconductor devices 101 and 103 may be any type of non-planar metal oxide semiconductor (MOS) transistor, such as a tri-gate, gate-all-around (GAA), or forksheet transistor, although other transistor topologies and types could also benefit from the techniques provided herein. The illustrated embodiments herein use the GAA structure.

First and second semiconductor devices 101 and 103 together represent a portion of an integrated circuit that may contain any number of similar semiconductor devices. Additionally, first and second semiconductor devices 101 and 103 are provided side-by-side for clarity and for ease of discussion when comparing and contrasting the devices. However, second semiconductor device 103 could exist anywhere else within the integrated circuit and is not required to be linked with first semiconductor device 101 via a shared source or drain region. The arrangement of first semiconductor device 101 sharing a source or drain region with second semiconductor device 103 may be used in various common circuit structures, such as an inverter.

As can be seen, semiconductor devices 101 and 103 are formed on a substrate 102. Any number of other semiconductor devices can be formed on substrate 102, but two are illustrated here as an example. Substrate 102 can be, for example, a bulk substrate including group IV semiconductor material (such as silicon, germanium, or silicon germanium), group III-V semiconductor material (such as gallium arsenide, indium gallium arsenide, or indium phosphide), and/or any other suitable material upon which transistors can be formed. Alternatively, substrate 102 can be a semiconductor-on-insulator (SOI) substrate having a desired semiconductor layer over a buried insulator layer (e.g., silicon over silicon dioxide). Alternatively, substrate 102 can be a multilayer substrate or superlattice suitable for forming nanowires or nanoribbons (e.g., alternating layers of silicon and SiGe, or alternating layers indium gallium arsenide and indium phosphide). Any number of substrates can be used.

First semiconductor device 101 may include any number of semiconductor nanoribbons 104 while second semiconductor device 103 similarly may include any number of semiconductor nanoribbons 106. Nanoribbons 104 may extend in a first direction (e.g., across the page) between a first source or drain 108 and a second source or drain region 110. Likewise, nanoribbons 106 may extend in the first direction between a third source or drain region 112 and second source or drain region 110. Any source region may also act as a drain region and vice versa, depending on the application. Furthermore, as noted above, nanoribbons 106 of second semiconductor device 103 may extend between third source or drain region 112 and another source or drain region that is different from second source or drain region 110.

In some embodiments, semiconductor devices 101 and 103 have an equal number of nanoribbons, while in other embodiments they have an unequal number of nanoribbons. In some embodiments, each of nanoribbons 104 and nanoribbons 106 are formed from a fin of alternating material layers (e.g., alternating layers of silicon and silicon germanium) where sacrificial material layers are removed between nanoribbons 104 and nanoribbons 106. Each of nanoribbons 104 and nanoribbons 106 may include the same semiconductor material as substrate 102, or not. In still other cases, substrate 102 is removed. In some such cases, there may be, for example one or more backside interconnect and/or contact layers.

According to some embodiments, source or drain regions 108/110/112 are epitaxial regions that are provided using an etch-and-replace process. In other embodiments any of the source or drain regions could be, for example, implantation-doped native portions of the semiconductor fins or substrate. Any semiconductor materials suitable for source or drain regions can be used (e.g., group IV and group III-V semiconductor materials). The source or drain regions may include multiple layers such as liners and capping layers to improve contact resistance. In any such cases, the composition and doping of the source or drain regions may be the same or different, depending on the polarity of the transistors. Any number of source or drain configurations and materials can be used.

A dielectric fill 113 may be formed over each of source or drain regions 108/110/112. Dielectric fill 113 may be any suitable dielectric material, such as silicon dioxide. In some embodiments, a conductive contact may be formed through dielectric fill 113 to make an electrical connection with the underlying source or drain region 108/110/112.

According to some embodiments, the fins or semiconductor material can be formed of material deposited over the underlying substrate 102. In one such example case, a blanket layer of silicon germanium (SiGe) can be deposited over a silicon substrate, and then patterned and etched to form a plurality of SiGe fins or nanoribbons. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins, or deposited into fin-shaped trenches.

According to some embodiments, a first gate structure is provided over each of nanoribbons 104 between spacer structures 114 and internal spacers 116. Similarly, a second gate structure is provided over each of nanoribbons 106 between spacer structures 114 and internal spacers 116. Each of the first and second gate structures may extend along a second direction (e.g., into and out of the page) across the corresponding semiconductor regions. According to some embodiments, the first gate structure includes a gate dielectric on nanoribbons 104, a first work function layer 118 on the gate dielectric, and a first conductive fill 120 on first work function layer 118. According to some embodiments, the second gate structure includes a gate dielectric on nanoribbons 106, a second work function layer 122 on the gate dielectric, and a second conductive fill 124 on second work function layer 122. The gate dielectric in both devices may also be deposited along sidewalls and the bottom of the gate trenches between spacer structures 114 and internal spacers 116. Note that the gate dielectrics are not illustrated for the sake of clarity. The gate dielectrics may include a single material layer or multiple stacked material layers. In some embodiments, the gate dielectrics include a first dielectric layer such as silicon oxide and a second dielectric layer that includes a high-K material such as hafnium oxide. The hafnium oxide may be doped with an element to affect the threshold voltage of the given semiconductor device. According to some embodiments, the doping element used in the gate dielectrics is lanthanum.

According to some embodiments, first work function layer 118 and second work function layer 122 may be conductive layers that can each include titanium (e.g., for a p-channel device) or tungsten (e.g., for an n-channel device). Other metals or metal alloys may be used as well. First conductive fill 120 and second conductive fill 124 may include any sufficiently conductive material such as a metal, metal alloy, or doped polysilicon. In some embodiments, both first conductive fill 120 and second conductive fill 124 include tungsten.

The first gate structure of semiconductor device 101 has a first width w₁ along the first direction and the second gate structure of semiconductor device 103 has a second width w₂ along the first direction that is greater than the first width, according to some embodiments. For example, second width w₂ may be at least 1.5×, at least 2×, at least 2.5×, at least 3×, or at least 5× greater than first width w₁. Although the absolute widths can vary from one example to the next, in one such example, the first width w₁ may be between about 30 nm and about 50 nm, with the second width w₂ being about 1.5 to about 5 times larger.

According to some embodiments, first work function layer 118 extends above a top surface of nanoribbons 104 (or any other suitable semiconductor region shape, such as a fin) by a first height h₁ and second work function layer 122 extends above a top surface of nanoribbons 106 (or any other suitable reference surface that is effectively common to both devices 101 and 103, such as an upper fin surface, or the surface of underlying substrate 102) by a second height h₂. According to some embodiments, first height h₁ is substantially the same as second height h₂. In other words, first height h₁ is within 1 nm or within 2 nm of second height h₂. In some examples, an imaginary horizontal line is substantially coplanar with the uppermost surfaces of both first work function layer 118 and second work function layer 122, such that the uppermost surfaces of first work function layer 118 and second work function layer 122 are within 1 nm of that imaginary line. In some embodiments, a CMP process having silica in the slurry is used to polish (planarize) a sacrificial material (e.g., CHM) used to pattern the upper height of both first work function layer 118 and second work function layer 122, so as to provide such coplanarity of the first work function layer 118 and second work function layer 122. Other applications of using the polishing process for CHM are discussed herein as well.

### Fabrication Methodology

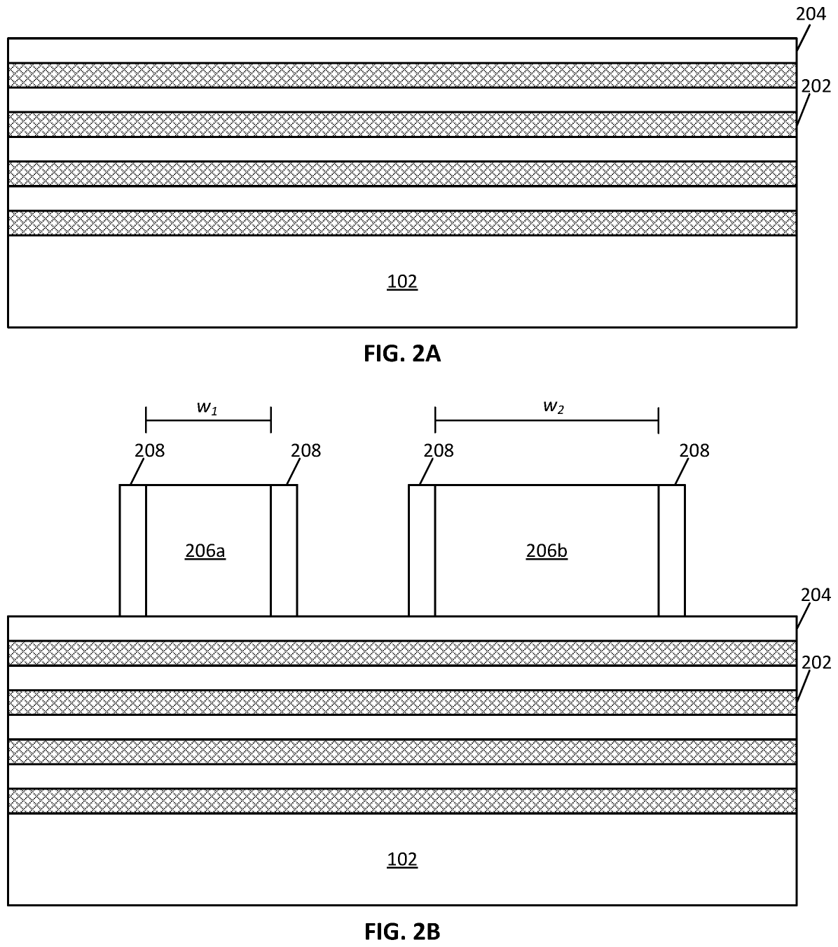

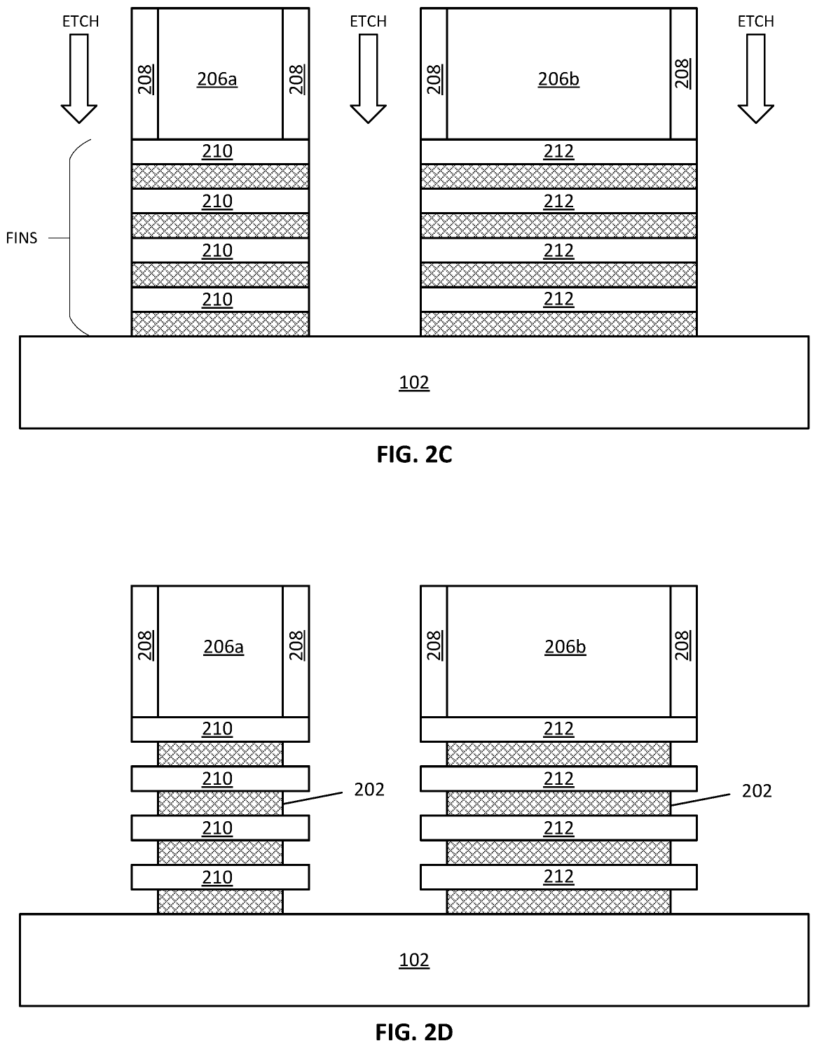

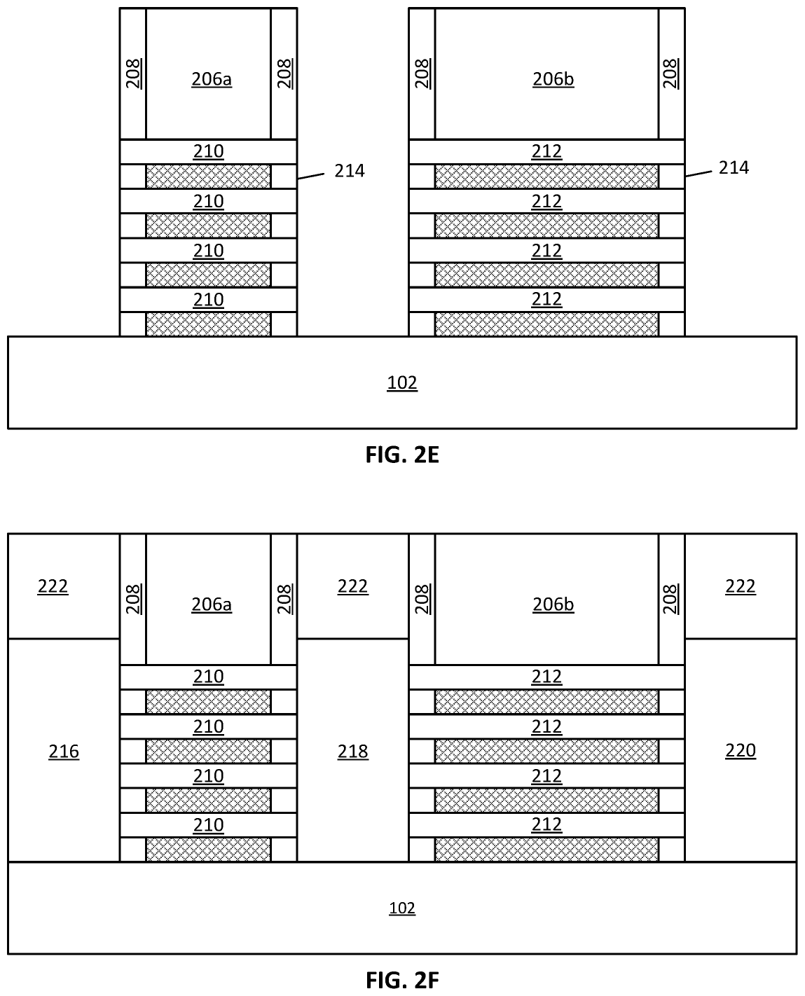

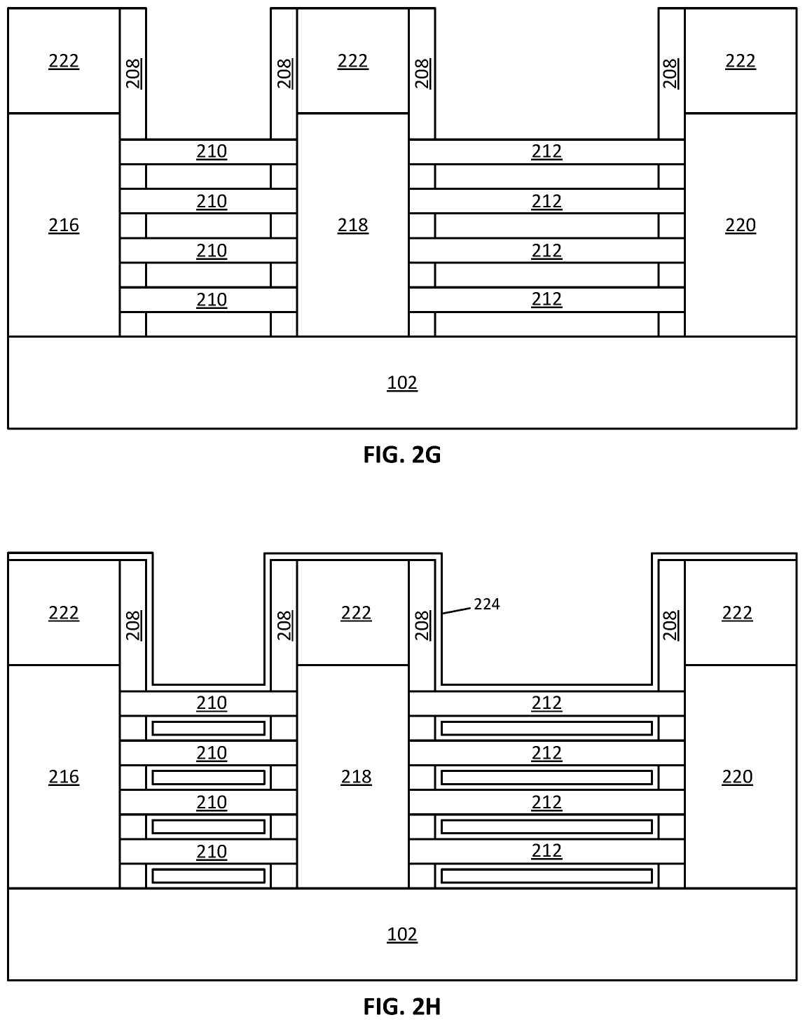

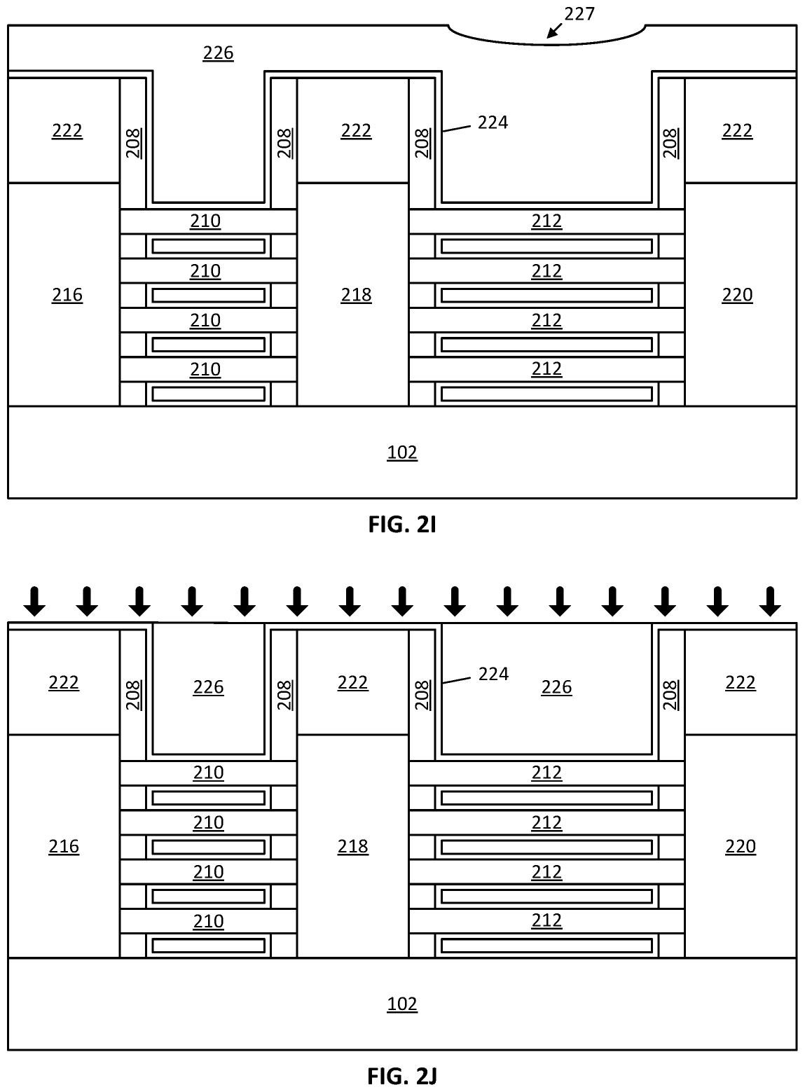

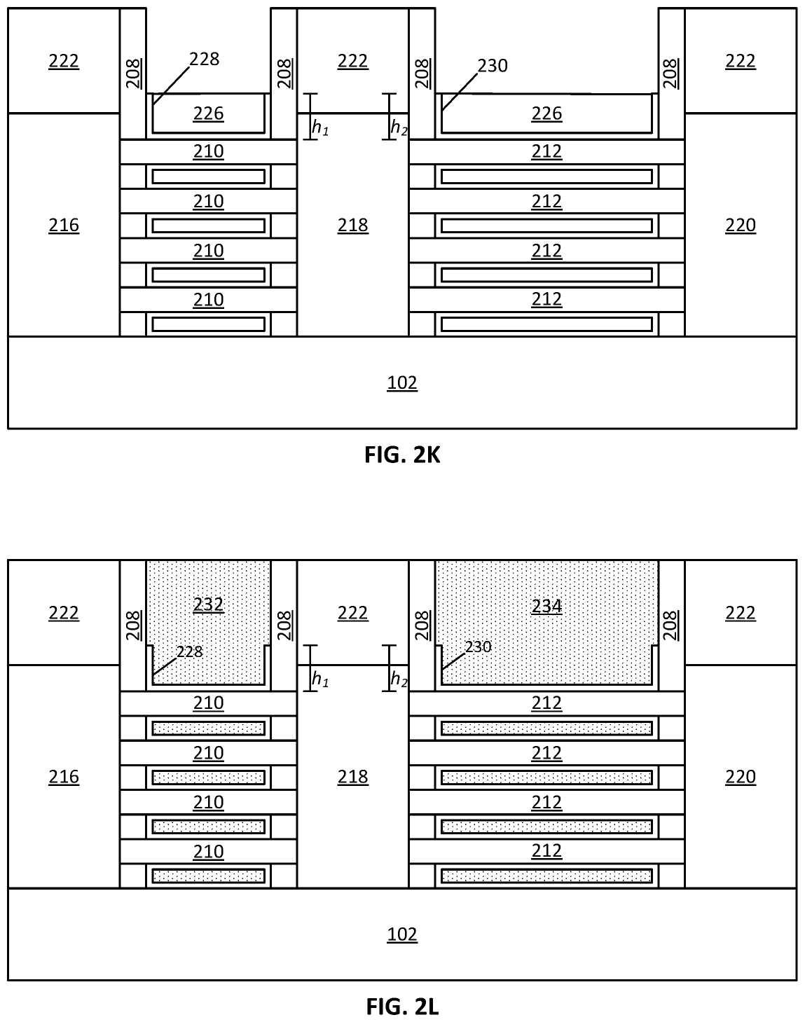

FIGS. 2A-2L include cross-sectional views that collectively illustrate an example process for forming an integrated circuit configured with semiconductor devices having work function layers that extend to substantially the same height within the respective gate trenches of the semiconductor devices, according to some embodiments. The fabrication process involves one or more CMP steps using a silica-based slurry to planarize CHM, according to some embodiments. Each figure shows an example structure that results from the process flow up to that point in time, so the depicted structure evolves as the process flow continues, culminating in the structure shown in FIG. 2L, which is similar to the structure shown in FIG. 1. The illustrated integrated circuit structure may be part of a larger integrated circuit that includes other integrated circuitry not depicted. Example materials and process parameters are given, but the present disclosure is not intended to be limited to any specific such materials or parameters, as will be appreciated.

FIG. 2A illustrates substrate 102 having a series of material layers formed over the substrate, according to an embodiment of the present disclosure. Alternating material layers may be deposited over substrate 102 including sacrificial layers 202 alternating with semiconductor layers 204. Any number of alternating semiconductor layers 204 and sacrificial layers 202 may be deposited over substrate 102. It should be noted that the cross-section illustrated in FIG. 2A is taken along the length of a fin formed from the multiple layers and extending up above the surface of substrate 102.

According to some embodiments, sacrificial layers 202 have a different material composition than semiconductor layers 204. In some embodiments, sacrificial layers 202 are silicon germanium (SiGe) while semiconductor layers 204 include a semiconductor material suitable for use as a nanoribbon such as silicon (Si), SiGe, germanium, or III-V materials like indium phosphide (InP) or gallium arsenide (GaAs). In examples where SiGe is used in each of sacrificial layers 202 and in semiconductor layers 204, the germanium concentration is different between sacrificial layers 202 and semiconductor layers 204. For example, sacrificial layers 202 may include a higher germanium content compared to semiconductor layers 204.

While dimensions can vary from one example embodiment to the next, the thickness of each sacrificial layer 202 may be between about 5 nm and about 20 nm. In some embodiments, the thickness of each sacrificial layer 202 is substantially the same (e.g., within 1-2 nm). The thickness of each of semiconductor layers 204 may be about the same as the thickness of each sacrificial layer 202 (e.g., about 5-20 nm). Each of sacrificial layers 202 and semiconductor layers 204 may be deposited using any known material deposition technique, such as chemical vapor deposition (CVD), plasma-enhanced chemical vapor deposition (PECVD), physical vapor deposition (PVD), or atomic layer deposition (ALD).

FIG. 2B illustrates a cross-sectional view of the structure shown in FIG. 2A following the formation of first sacrificial gate structure 206a and second sacrificial gate structure 206b and spacer structures 208 over the alternating layer structure of the fin, according to an embodiment. Sacrificial gate structures 206a and 206b may run in an orthogonal direction to the length of the fin and may include any material that can be safely removed later in the process without etching or otherwise damaging any portions of the fin or of spacer structures 208. In some embodiments, sacrificial gate structures 206a and 206b include polysilicon. Spacer structures 208 may be formed using an etch-back process where spacer material is deposited everywhere and then anisotropically etched to leave the material only on sidewalls of structures including sacrificial gate structures 206a and 206b. Spacer structures 208 may include a dielectric material, such as silicon nitride, silicon oxy-nitride, or any formulation of those layers incorporating carbon or boron dopants. Sacrificial gate structures 206a and 206b together with spacer structures 208 define portions of the fin that will be used to form first and second semiconductor devices, respectively, as discussed further herein.

According to some embodiments, first sacrificial gate structure 206a has a first width w₁ along a length of the underlying fin and second sacrificial gate structure 206b has a second width w₂ along the length of the underlying fin that is greater than the first width w₁. For example, second width w₂ may be at least 1.5×, at least 2×, at least 2.5×, at least 3×, or at least 5× greater than first width w₁. First width w₁ may be between about 30 nm and about 50 nm.

FIG. 2C illustrates a cross-sectional view of the structure shown in FIG. 2B following the removal of the exposed fin not under sacrificial gate structures 206a/206b and spacer structures 208, according to an embodiment of the present disclosure. According to some embodiments, the various alternating material layers are etched at substantially the same rate using an anisotropic RIE process. In some embodiments, some undercutting occurs along the edges of the resulting fins beneath spacer structures 208 such that the length of a given fin is not exactly the same as a sum of the widths of spacer structures 208 and a width of sacrificial gate structures 206a/206b. The RIE process may also etch into substrate 102 thus recessing portions of substrate 102 on either side of any of the fins. According to some embodiments, a first fin includes first semiconductor layers 210 while a second fin includes second semiconductor layers 212.

FIG. 2D illustrates a cross-sectional view of the structure shown in FIG. 2C following the removal of portions of sacrificial layers 202, according to an embodiment of the present disclosure. An isotropic etching process may be used to recess the exposed ends of each sacrificial layer 202.

FIG. 2E illustrates a cross-sectional view of the structure shown in FIG. 2D following the formation of internal spacers 214, according to an embodiment of the present disclosure. Internal spacers 214 may have a material composition that is similar to or the exact same as spacer structures 208. Accordingly, internal spacers 214 may be any suitable dielectric material that exhibits high etch selectively to semiconductor materials such as silicon and/or silicon germanium. Internal spacers 214 may be, for example, conformally deposited over the sides of the fin structure using a conformal deposition process like CVD or ALD and then etched back using an isotropic etching process to expose the ends of first semiconductor layers 210 and second semiconductor layers 212.

FIG. 2F illustrates a cross-sectional view of the structure shown in FIG. 2E following the formation of source or drain regions, according to an embodiment of the present disclosure. According to an embodiment, a first source or drain region 216 is formed at first ends of first semiconductor layers 210 and a second source or drain region 218 is formed between second ends of first semiconductor layers 210 and first ends of second semiconductor layers 212. A third source or drain region 220 may be formed at second ends of second semiconductor layers 212. As noted above, any of source or drain regions 216/218/220 can act as either a source or drain depending on the application. In some examples, source or drain regions 216/218/220 are epitaxially grown from the ends of semiconductor layers 210 and 212. Any semiconductor materials suitable for source or drain regions 216/218/220 can be used (e.g., group IV and group III-V semiconductor materials). Source or drain regions 216/218/220 may include multiple layers such as liners and capping layers to improve contact resistance. In any such cases, the composition and doping of source or drain regions 216/218/220 may be the same or different, depending on the polarity of the transistors. Any number of source or drain configurations and materials can be used.

A dielectric cap layer 222 may be formed over each of source or drain regions 216/218/220, according to some embodiments. Dielectric cap layer 222 allows for a planarized structure, such that the top surfaces of sacrificial gate structures 206a/206b are substantially coplanar with the top surface of dielectric cap layer 222. Dielectric cap layer 222 may be any suitable dielectric material, such as silicon oxide, aluminum oxide, silicon nitride, or silicon oxycarbonitride.

FIG. 2G illustrates a cross-sectional view of the structure shown in FIG. 2F following the removal of the sacrificial gate structures 206a/206b and sacrificial layers 202, according to an embodiment of the present disclosure. The sacrificial gate structures 206a/206b may be removed using any wet or dry isotropic process thus exposing the alternating layer stack of the fins within the trenches left behind after the removal of sacrificial gate structures 206a/206b. Once sacrificial gate structures 206a/206b have been removed, the exposed sacrificial layers 202 may also be removed using a selective isotropic etching process that removes the material of sacrificial layers 202 but does not remove (or removes very little of) first semiconductor layers 210 and second semiconductor layers 212. At this point, the suspended first semiconductor layers 210 form nanoribbons or nanowires that extend between source or drain regions 216/218 and the suspended second semiconductor layers 212 form nanoribbons or nanowires that extend between source or drain regions 218/220.

At this stage, a gate dielectric may be formed over each of first semiconductor layers 210 and second semiconductor layers 212. The gate dielectric is not illustrated for clarity and to provide more focus on the work function layers discussed with reference to FIG. 2H. The gate dielectric may be conformally deposited using any suitable deposition process, such as ALD. The gate dielectric may include any suitable dielectric (such as silicon dioxide, and/or a high-k dielectric material). Examples of high-k dielectric materials include, for instance, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate, to provide some examples. According to some embodiments, the gate dielectric is hafnium oxide with a thickness between about 1 nm and about 5 nm. In some embodiments, the gate dielectric may include one or more silicates (e.g., titanium silicate, tungsten silicate, niobium silicate, and silicates of other transition metals). The gate dielectric may be a multilayer structure, in some examples. For instance, the gate dielectric may include a first layer on first semiconductor layers 210 and second semiconductor layers 212, and a second layer on the first layer. The first layer can be, for instance, an oxide of the semiconductor layers (e.g., silicon dioxide) and the second layer can be a high-k dielectric material (e.g., hafnium oxide). In some embodiments, an annealing process may be carried out on the gate dielectric to improve its quality when a high-k dielectric material is used. In some embodiments, the high-K material can be nitridized to improve its aging resistance.

FIG. 2H illustrates a cross-sectional view of the structure shown in FIG. 2G following the formation of a work function layer 224 within the gate trenches, according to some embodiments. As noted above, work function layer 224 may be deposited over a previously-formed gate dielectric. Work function layer 224 may be deposited using any suitable deposition process, such as ALD to a thickness between about 2 nm and about 5 nm. Work function layer 224 may include any suitable conductive material, such as any metal or metal alloy. In some examples, work function layer 224 includes titanium or tungsten.

In the illustrated embodiment, the same work function layer 224 is formed within both gate trenches that include first semiconductor layers 210 and second semiconductor layer 212. This may be done if both semiconductor devices are the same type (e.g., both n-channel devices or both p-channel devices). However, in some embodiments, a different work function layer is formed within each gate trench, which allows for different materials to be used between the different work function layers. In this way, one device may be an n-channel device while the other device is a p-channel device.

FIG. 2I illustrates a cross-sectional view of the structure shown in FIG. 2H following the formation of a sacrificial material 226 on work function layer 224 and within each of the gate trenches of both devices, according to some embodiments. In an example, sacrificial material 226 is CHM deposited via spin-coating. Due to the difference in width between the gate trenches, sacrificial material 226 may exhibit some sag 227 above the wider gate trench, and the flowable nature of the spun-on CHM. If sacrificial material 226 were recessed down into both gate trenches using a wet or dry etching process (sometimes called an etch-back process), the final height of sacrificial material 226 within each gate trench would not be the same due to the presence of the sag 227.

FIG. 2J illustrates a cross-sectional view of the structure shown in FIG. 2I following a polishing process using CMP as indicated by the bold arrows, according to some embodiments. In this example, a silica-based slurry is used during a CMP process to selectively polish back sacrificial material 226. In contrast, and as noted above, if an etch-back process was used, the non-planar surface of sacrificial material 226 would persist, including the dimple associated with sag 227, given the uniform or non-selective nature of the etch-back process. According to an example of the present description, the silica-based slurry has been found to be especially effective at selectively polishing CHM. According to some embodiments, the polishing process yields a top surface of sacrificial material 226 within each gate trench that is substantially coplanar with a top surface of work function layer 224 outside of the gate trenches. As used herein, two surfaces are considered to be substantially coplanar if they are polished together using the same CMP process. In another example, the height variation between two surfaces that are substantially coplanar may be less than 1 nm. In another example of coplanarity, each of the two surfaces varies no more than 1 nm from an imaginary horizontal plane that passes through or is otherwise common to both surfaces.

FIG. 2K illustrates a cross-sectional view of the structure shown in FIG. 2J following the recessing of sacrificial material 226 within both gate trenches and subsequent removal of the portions of work function layer 224 not protected by sacrificial material 226, according to some embodiments. Work function layer 224 may be separated into a first work function layer 228 within the first gate trench and a second work function layer 230 within the second gate trench. Sacrificial material 226 may be recessed using any known wet or dry isotropic etching process. Due to the earlier CMP process, the final height of sacrificial material 226 within both gate trenches can be made to be substantially equal following the recessing. As a result, first work function layer 228 extends above first semiconductor layers 210 to a first height h₁ while second work function layer 230 extends above second semiconductor layers 212 to a second height h₂ that is substantially the same as first height h₁. For example, first height h₁ and second height h₂ may be within 2 nm of each other or within 1 nm of each other.

FIG. 2L illustrates a cross-sectional view of the structure shown in FIG. 2K following the removal of sacrificial material 226 and the formation of first conductive fill 232 and second conductive fill 234, according to some embodiments. Sacrificial material 226 may be removed using an ashing process or any other suitable process that removes sacrificial material 226 without damaging any other structures. Each of first conductive fill 232 and second conductive fill 234 can include any suitable metal or metal alloy, such as aluminum, tungsten, cobalt, molybdenum, ruthenium, titanium, tantalum, copper, or carbides/nitrides thereof. First conductive fill 232 and second conductive fill 234 may be deposited, for example, using CVD and polished using CMP such that a top surface of each of first conductive fill 232 and second conductive fill 234 is substantially coplanar with a top surface of spacer structures 208.

FIGS. 2I-2L illustrate how using a silica-based CMP process to polish CHM can result in improved devices by ensuring that work function layers extend up to the same height or plane within their respective gate trenches, even when the trenches have different widths.

A variation on the methodology can be used in the context of spacer-based patterning. In more detail, spacer-based patterning includes the formation of gratings that can be used to make metal trenches, or vias to connect metal layers to a gate structure or diffusion contact, and dielectric plugs for trenches. Such a structure is shown in FIG. 2B, which is similar to a grating with backbone features (e.g., 206a-b) and spacers (e.g., 208), except assume that the structure further includes two groups of differently-spaced backbone features. Such a structure could be filled with flowable CHM and then planarized down to the tops of spacers 208 via a CHM polish as described herein. The backbone features can then be selectively etched away to leave the diverse-pitch pattern of spacers 208, and the remaining CHM can then be removed (via an ashing process). The diverse-pitch pattern of spacers 208 can then be used to pattern an underlying layer so as to form conductive lines or dielectric plugs, or other such repetitive spaced features. Just as discussed with respect to gate structure formation, if CHM etch-back was used to form the diverse-pitch pattern of spacers, the CHM would be etched lower than the top of grating (spacers) in locations where the grating pitch is larger than the smaller pitch areas. In contrast, a CMP technique as described herein selectively planarizes and more uniformly lands on top of the grating, which in turn prevents or otherwise reduces CHM height variation across different grating pitches.

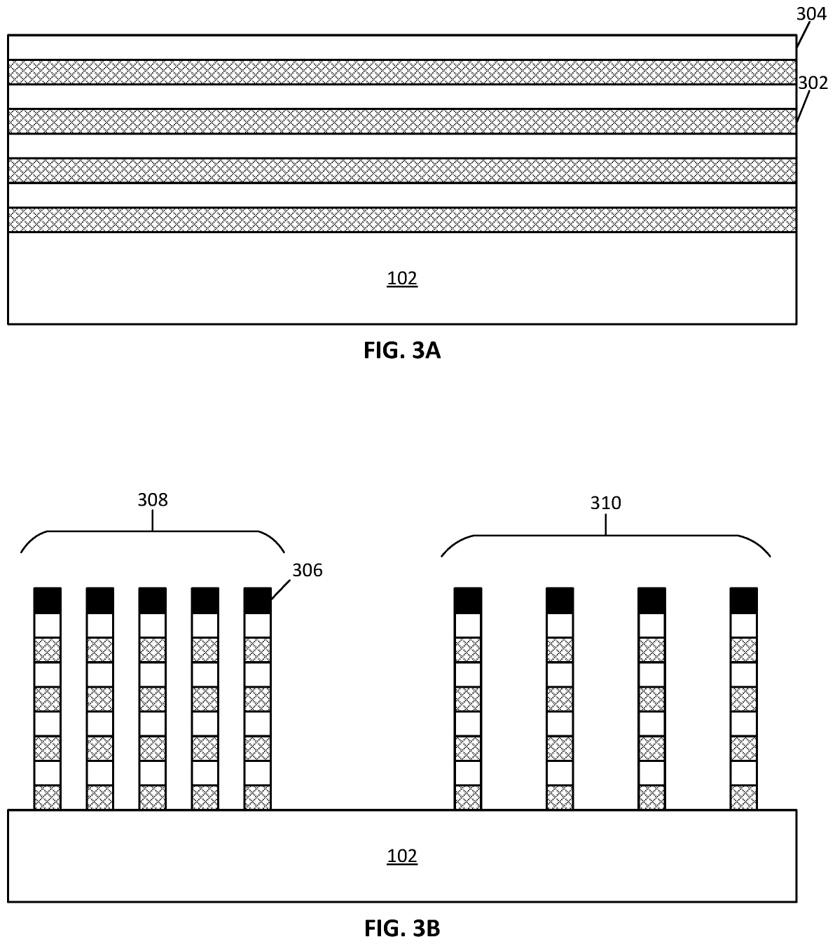

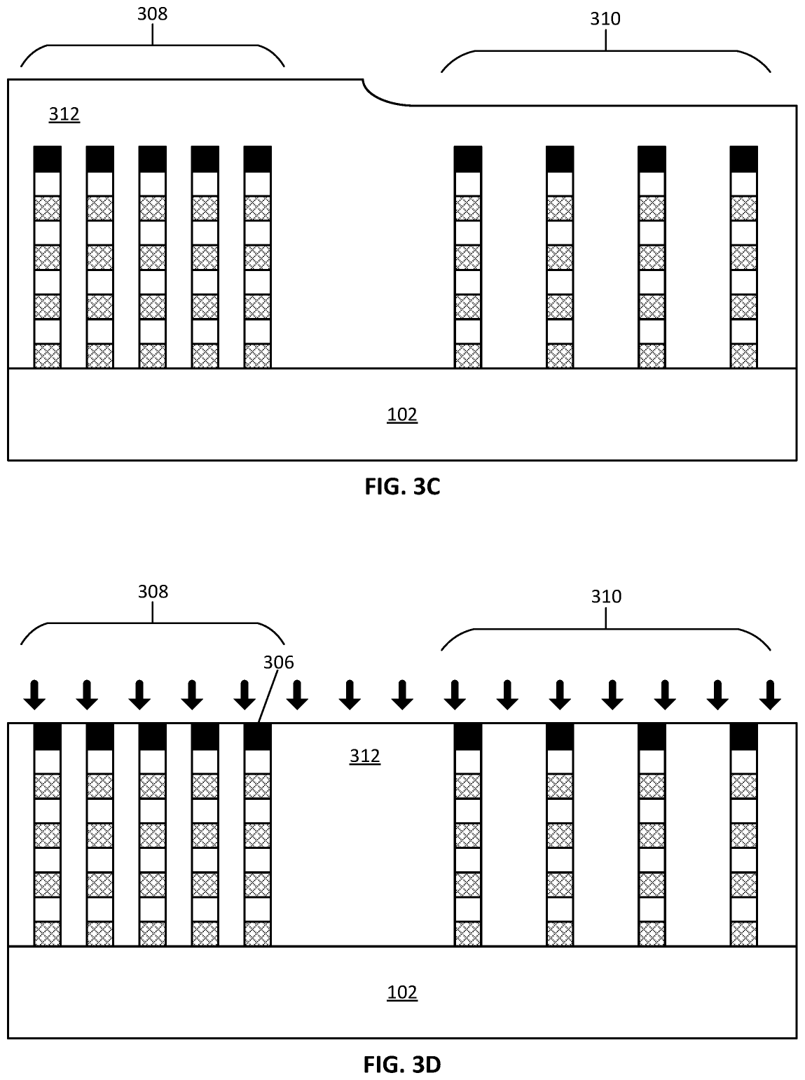

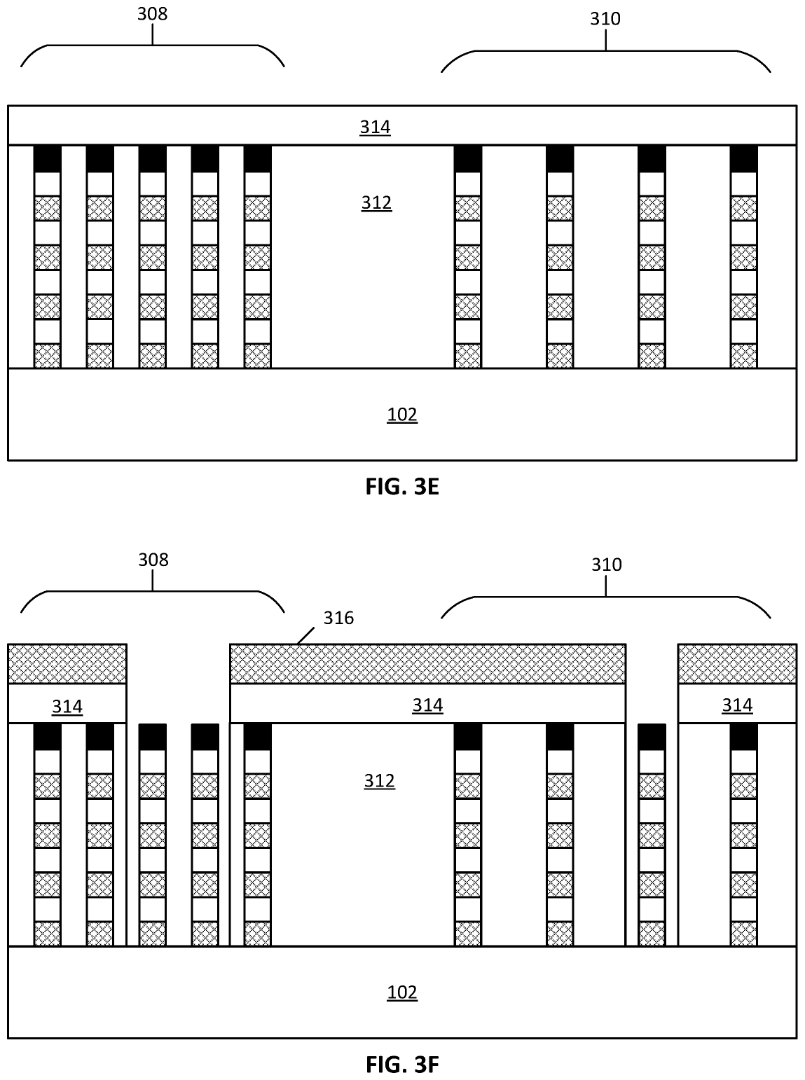

FIGS. 3A-3F illustrate another example use of CHM to remove fins, and how the silica-based CMP process can be used to improve the process. FIG. 3A illustrates substrate 102 having a series of material layers formed over the substrate, according to an embodiment of the present disclosure. Alternating material layers may be deposited over substrate 102 including sacrificial layers 302 alternating with semiconductor layers 304. Any number of alternating semiconductor layers 304 and sacrificial layers 302 may be deposited over substrate 102. Details of semiconductor layers 304 and sacrificial layers 302 are similar to those discussed above with reference to FIG. 2A and semiconductor layers 204 and sacrificial layers 202, and that above relevant description is equally applicable here.

FIG. 3B depicts the cross-section view of the structure shown in FIG. 3A following the deposition of a cap layer 306 and the subsequent formation of fins beneath cap layer 306, according to an embodiment. Cap layer 306 may be deposited via ALD, CVD or other suitable deposition process, and may be any suitable hard mask material such as a carbon hard mask (CHM) or silicon nitride. Cap layer 306 is patterned into rows to form corresponding rows of fins from the alternating layer stack of sacrificial layers 302 and semiconductor layers 304. The rows of fins extend lengthwise in a first direction (e.g., into and out of the page).

According to some embodiments, fins in different areas of substrate 102 may have different fin densities. For example, a first group of fins 308 may be formed with a first fin density and a second group of fins 310 may be formed with a second fin density lower than the first fin density. Any number of groups of fins may be formed in this way with any number of different fin densities.

FIG. 3C depicts the cross-section view of the structure shown in FIG. 3B following the formation of a sacrificial material 312 over both first group of fins 308 and second group of fins 310, according to some embodiments. In an example, sacrificial material 312 is CHM. Due to the lower fin density of second group of fins 310, sacrificial material 312 may have a decreased height over second group of fins 310 compared to first group of fins 308. Sacrificial material 312 may be deposited, for example, using spin coating or CVD.

FIG. 3D depicts the cross-section view of the structure shown in FIG. 3C following a polishing process using CMP as indicated by the bold arrows, according to some embodiments. A silica-based slurry is used during a CMP process to polish back sacrificial material 312. The silica-based slurry has been found to be especially effective at selectively polishing CHM. According to some embodiments, the polishing process yields a top surface of sacrificial material 312 that is substantially coplanar with a top surface of cap layer 306.

FIG. 3E depicts the cross-section view of the structure shown in FIG. 3D following the formation of a sacrificial layer 314 over sacrificial material 312, according to some embodiments. Sacrificial layer 314 may be the same material as sacrificial material 312. For example, both sacrificial layer 314 and sacrificial material 312 can be CHM.

FIG. 3F depicts the cross-section view of the structure shown in FIG. 3E following the formation of mask layer 316 over sacrificial layer 314, according to some embodiments. Mask layer 316 may be any suitable dielectric mask material, such as silicon nitride or silicon dioxide. In some embodiments, one or more openings are formed through mask layer 316 and the exposed portions of sacrificial layer 314 and sacrificial material 312 are removed beneath the one or more openings in mask layer 316. This process exposes one or more fins to be removed from first group of fins 308 and second group of fins 310.

It should be noted that the example application of using CMP for CHM polishing described with reference to FIGS. 3A-3F may be applied to many other similar situations. For example, grating structures having different pitches (similar to the fins having different densities) can be formed by depositing CHM over the grating structures and polishing the CHM back to the top surfaces of the grating structure using a silica-based CMP process. In another example, the patterning of via connections to gate structures and source/drain contacts can be facilitated by using dielectric helmet structures over the source/drain contacts and CHM between and over the helmet structures. The CHM can then be polished back to expose the top surfaces of the helmet structures and allow for openings to be formed down to the gate structures. In another example, CHM may be deposited over epitaxial regions (e.g., source/drain regions) and then polished back and recessed to protect the epitaxial regions while nodule defects within the upper exposed spacer structures are etched away. Any other applications that use CHM will be apparent based on the examples provided.

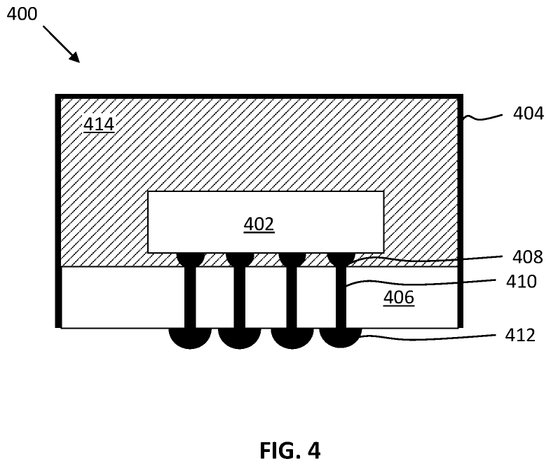

FIG. 4 illustrates an example embodiment of a chip package 400, in accordance with an embodiment of the present disclosure. As can be seen, chip package 400 includes one or more dies 402. One or more dies 402 may include at least one integrated circuit having semiconductor devices, such as any of the semiconductor devices disclosed herein. One or more dies 402 may include any other circuitry used to interface with other devices formed on the dies, or other devices connected to chip package 400, in some example configurations.

As can be further seen, chip package 400 includes a housing 404 that is bonded to a package substrate 406. The housing 404 may be any standard or proprietary housing, and may provide, for example, electromagnetic shielding and environmental protection for the components of chip package 400. The one or more dies 402 may be conductively coupled to a package substrate 406 using connections 408, which may be implemented with any number of standard or proprietary connection mechanisms, such as solder bumps, ball grid array (BGA), pins, or wire bonds, to name a few examples. Package substrate 406 may be any standard or proprietary package substrate, but in some cases includes a dielectric material having conductive pathways (e.g., including conductive vias and lines) extending through the dielectric material between the faces of package substrate 406, or between different locations on each face. In some embodiments, package substrate 406 may have a thickness less than 1 millimeter (e.g., between 0.1 millimeters and 0.5 millimeters), although any number of package geometries can be used. Additional conductive contacts 412 may be disposed at an opposite face of package substrate 406 for conductively contacting, for instance, a printed circuit board (PCB). One or more vias 410 extend through a thickness of package substrate 406 to provide conductive pathways between one or more of connections 408 to one or more of contacts 412. Vias 410 are illustrated as single straight columns through package substrate 406 for ease of illustration, although other configurations can be used (e.g., damascene, dual damascene, through-silicon via, or an interconnect structure that meanders through the thickness of substrate 406 to contact one or more intermediate locations therein). In still other embodiments, vias 410 are fabricated by multiple smaller stacked vias, or are staggered at different locations across package substrate 406. In the illustrated embodiment, contacts 412 are solder balls (e.g., for bump-based connections or a ball grid array arrangement), but any suitable package bonding mechanism may be used (e.g., pins in a pin grid array arrangement or lands in a land grid array arrangement). In some embodiments, a solder resist is disposed between contacts 412, to inhibit shorting.

In some embodiments, a mold material 414 may be disposed around the one or more dies 402 included within housing 404 (e.g., between dies 402 and package substrate 406 as an underfill material, as well as between dies 402 and housing 404 as an overfill material). Although the dimensions and qualities of the mold material 414 can vary from one embodiment to the next, in some embodiments, a thickness of mold material 414 is less than 1 millimeter. Example materials that may be used for mold material 414 include epoxy mold materials, as suitable. In some cases, the mold material 414 is thermally conductive, in addition to being electrically insulating.

### Methodology

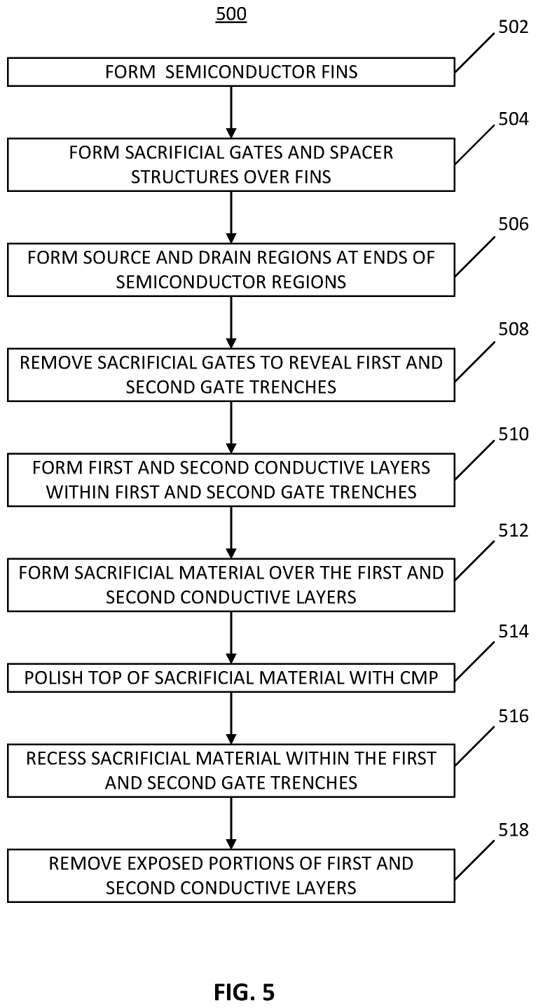

FIG. 5 is a flow chart of a method 500 for forming at least a portion of an integrated circuit, according to an embodiment. Various operations of method 500 may be illustrated in FIGS. 2A-2L. However, the correlation of the various operations of method 500 to the specific components illustrated in the aforementioned figures is not intended to imply any structural and/or use limitations. Rather, the aforementioned figures provide one example embodiment of method 500. Other operations may be performed before, during, or after any of the operations of method 500. Some of the operations of method 500 may be performed in a different order than the illustrated order.

Method 500 begins with operation 502 where any number of parallel semiconductor fins are formed, according to some embodiments. The semiconductor material in the fins may be formed from a substrate such that the fins are an integral part of the substrate (e.g., etched from a bulk silicon substrate). Alternatively, the fins can be formed of material deposited onto an underlying substrate. In one such example case, a blanket layer of silicon germanium (SiGe) can be deposited onto a silicon substrate, and then patterned and etched to form a plurality of SiGe fins extending from that substrate. In another such example, the fins include alternating layers of material (e.g., alternating layers of silicon and SiGe) that facilitates forming of nanowires and nanoribbons during a gate forming process where one type of the alternating layers are selectively etched away so as to liberate the other type of alternating layers within the channel region, so that a gate-all-around (GAA) process can then be carried out. The alternating layers can be blanket deposited and then etched into fins or deposited into fin-shaped trenches. The fins may also include a cap structure over each fin that is used to define the locations of the fins during, for example, an RIE process. The cap structure may be a dielectric material, such as silicon nitride.

Method 500 continues with operation 504 where sacrificial gates and spacer structures are formed over the fins. The sacrificial gates may be patterned using gate masking layers in strips that run orthogonally over the fins (many gate masking layers and corresponding sacrificial gates may be formed parallel to one another (e.g., forming a cross-hatch pattern with the fins). The gate masking layers may be any suitable hard mask material, such as CHM or silicon nitride. The sacrificial gates may be formed from any suitable material that can be selectively removed at a later time without damaging the semiconductor material of the fins. In one example, the sacrificial gates include polysilicon. The spacer structures may be deposited and then etched back such that the spacer structures remain mostly only on sidewalls of any exposed structures. According to some embodiments, the spacer structures may be any suitable dielectric material, such as silicon nitride or silicon oxynitride. One or more of the sacrificial gates may be wider (e.g., wider strips) compared to other sacrificial gates.

Method 500 continues with operation 506 where source or drain regions are formed at the ends of the semiconductor regions of each of the fins. Any portions of the fins not protected by the sacrificial gate and spacer structures may be removed using, for example, an anisotropic etching process followed by the epitaxial growth of the source or drain regions from the exposed ends of the semiconductor layers in the fins. In some example embodiments, the source or drain regions are NMOS source or drain regions (e.g., epitaxial silicon) or PMOS source or drain regions (e.g., epitaxial SiGe). Another dielectric fill may be formed adjacent to the various source or drain regions for additional electrical isolation between adjacent regions. The dielectric fill may also extend over a top surface of the source or drain regions. In some embodiments, topside conductive contacts may be formed through the dielectric fill to contact one or more of the source or drain regions.

Method 500 continues with operation 508 where the sacrificial gates are removed. The sacrificial gates may be removed using an isotropic etching process that selectively removes all of the material from the sacrificial gates, thus exposing the various fins between the set of spacer structures. In the example case where GAA transistors are used, any sacrificial layers within the exposed fins between the spacer structures may also be removed to release nanoribbons, nanosheets, or nanowires of semiconductor material. According to some embodiments, removal of a given sacrificial gate having a first width reveals a first gate trench and removal of a given sacrificial gate having a second width greater than the first width reveals a second gate trench. Accordingly, the second gate trench is wider than the first gate trench.

Method 500 continues with operation 510 where a first conductive layer is formed within the first gate trench and a second conductive layer is formed in the second gate trench. The first and second conductive layers may be work function layers deposited using a conformal deposition technique, such as ALD, to a thickness between about 2 nm and about 5 nm. Each of the first and second conductive layers may include any suitable conductive material, such as any metal or metal alloy. In some examples, the first and second conductive layers include titanium or tungsten. Due to the conformal nature of the deposition, the first and second conductive layers extend the entire height of the sidewalls within each of the first gate trench and the second trench, respectively.

Method 500 continues with operation 512 where a sacrificial material is formed on the first and second conductive layers within each of the first and second gate trenches. The sacrificial material may also be formed outside of the first and second gate trenches over the spacer structures. In an example, the sacrificial material is CHM and may be deposited using spin-coating or CVD. Due to the difference in width between the gate trenches, the sacrificial material may exhibit some sag above the wider second gate trench.

Method 500 continues with operation 514 where a polishing process using CMP is used to planarize the top surface of the sacrificial material. According to some embodiments, a silica-based slurry is used during a CMP process to polish back the sacrificial material. The silica-based slurry has been found to be especially effective at selectively polishing CHM. According to some embodiments, the polishing process yields a top surface of the sacrificial material within the first gate trench that is substantially coplanar with a top surface of the sacrificial material in the second gate trench.

Method 500 continues with operation 516 where the sacrificial material is recessed within both the first and second gate trenches. The sacrificial material may be recessed using any known wet or dry isotropic etching process. Due to the CMP process from operation 514, the final height of the sacrificial material within the first and the second gate trenches can be made to be substantially equal following the recessing. Thus, the recessing process yields a top surface of the sacrificial material within the first gate trench that is substantially coplanar with (e.g., within 1 nm of) a top surface of the sacrificial material in the second gate trench.

Method 500 continues with operation 518, where the exposed portions of the first conductive layer and the second conductive layer are removed. According to some embodiments, the recessed sacrificial material within each of the first and second gate trenches protects portions of the first and second conductive layers from being removed. As a result, the protected portions of the first conductive layer extend to a first height within the first gate trench while the protected portions of the second conductive layer extend to a second height within the second gate trench, where the second height is substantially the same as the first height. For example, the first height and the second height may be within 2 nm of each other or within 1 nm of each other.

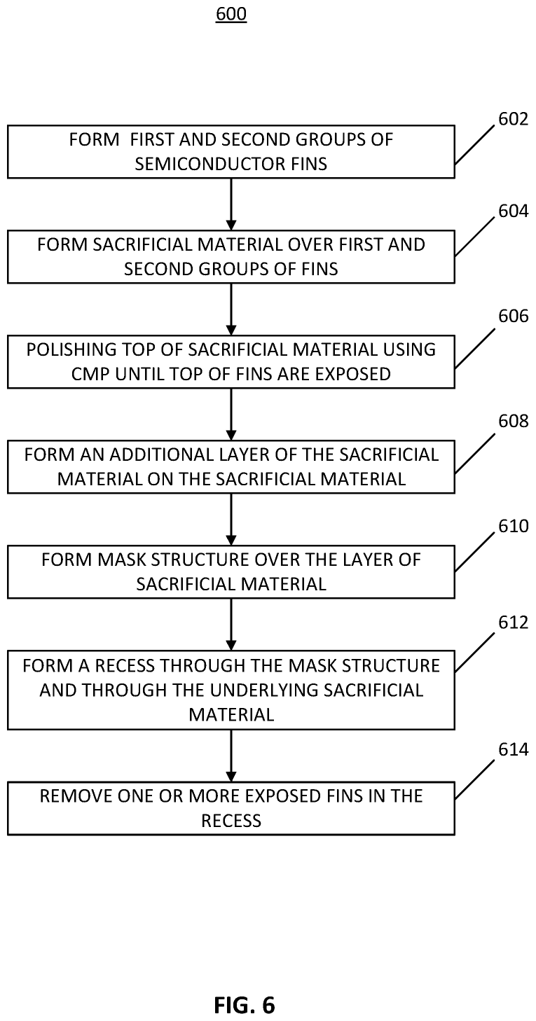

FIG. 6 is a flow chart of a method 600 for forming at least a portion of an integrated circuit, according to an embodiment. Various operations of method 600 may be illustrated in FIGS. 3A-3F. However, the correlation of the various operations of method 600 to the specific components illustrated in the aforementioned figures is not intended to imply any structural and/or use limitations. Rather, the aforementioned figures provide one example embodiment of method 600. Other operations may be performed before, during, or after any of the operations of method 600. Some of the operations of method 600 may be performed in a different order than the illustrated order.

Method 600 begins with operation 602 where first and second groups of semiconductor fins are formed on a substrate. The semiconductor material in the fins may be formed from a substrate such that the fins are an integral part of the substrate (e.g., etched from a bulk silicon substrate). Alternatively, the fins can be formed of material deposited onto an underlying substrate. The fins may also include a cap structure over each fin that is used to define the locations of the fins during, for example, an RIE process. The cap structure may be a dielectric material, such as silicon nitride. According to some embodiments, the first group of fins includes any number of fins having a first fin density (e.g., spacing between fins) and the second group of fins includes any number of fins having a second fin density lower than the first fin density.

Method 600 continues with operation 604 where a sacrificial material is formed over both the first and second groups of fins. In an example, the sacrificial material is CHM. Due to the lower fin density of the second group of fins, the sacrificial material may have a decreased height over the second group of fins compared to the first group of fins. The sacrificial material may be deposited, for example, using spin-coating or CVD.

Method 600 continues with operation 606 where a top surface of the sacrificial material is polished using CMP. According to some embodiments, the sacrificial material is polished using a CMP process with a silica-based slurry until a top surface of the fins (or the cap structures on the fins) is exposed.

Method 600 continues with operation 608 where an additional sacrificial layer is formed over the sacrificial material. The additional sacrificial layer may be deposited using spin-coating or CVD and may be the same material as the sacrificial material. For example, both the sacrificial layer and the sacrificial material can be CHM.

Method 600 continues with operation 610 where a mask structure is formed over the sacrificial layer. The mask structure may include any suitable dielectric mask material, such as silicon nitride or silicon dioxide. The mask structure may be deposited, for example, using CVD or ALD.

Method 600 continues with operation 612 where one or more openings are formed through the mask structure and recesses are formed through the underlying sacrificial layer and sacrificial material beneath the one or more openings. The openings and subsequent recessing may be performed using RIE or any other suitable anisotropic etching process. The removal of the sacrificial material exposes one or more fins from either or both the first and second groups of fins.

Method 600 continues with operation 614 where one or more of the exposed fins are removed. The fins may be removed using an additional RIE process or an isotropic etch. In some embodiments, the RIE process used in operation 612 removes both the sacrificial material and the fins beneath the one or more openings.

### Example System

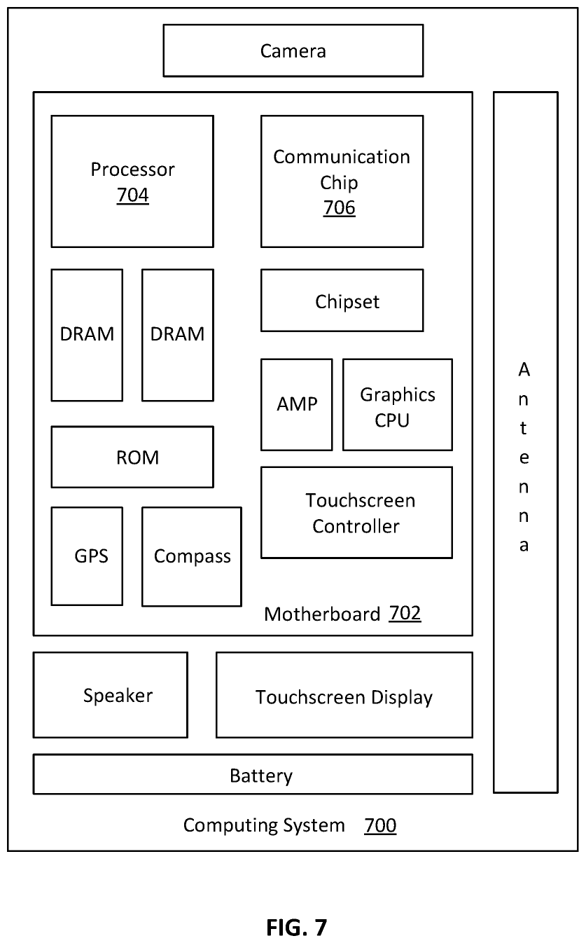

FIG. 7 is an example computing system implemented with one or more of the integrated circuit structures as disclosed herein, in accordance with some embodiments of the present disclosure. As can be seen, the computing system 700 houses a motherboard 702. The motherboard 702 may include a number of components, including, but not limited to, a processor 704 and at least one communication chip 706, each of which can be physically and electrically coupled to the motherboard 702, or otherwise integrated therein. As will be appreciated, the motherboard 702 may be, for example, any printed circuit board (PCB), whether a main board, a daughterboard mounted on a main board, or the only board of system 700, etc.

Depending on its applications, computing system 700 may include one or more other components that may or may not be physically and electrically coupled to the motherboard 702. These other components may include, but are not limited to, volatile memory (e.g., DRAM), non-volatile memory (e.g., ROM), a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth). Any of the components included in computing system 700 may include one or more integrated circuit structures or devices configured in accordance with an example embodiment (e.g., a module including an integrated circuit on a substrate, the substrate having semiconductor devices, as variously provided herein). In some embodiments, multiple functions can be integrated into one or more chips (e.g., for instance, note that the communication chip 706 can be part of or otherwise integrated into the processor 704).

The communication chip 706 enables wireless communications for the transfer of data to and from the computing system 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including, but not limited to, Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing system 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing system 700 includes an integrated circuit die packaged within the processor 704. In some embodiments, the integrated circuit die of the processor includes onboard circuitry that is implemented with one or more semiconductor devices as variously described herein. The term “processor” may refer to any device or portion of a device that processes, for instance, electronic data from registers and/or memory to transform that electronic data into other electronic data that may be stored in registers and/or memory.

The communication chip 706 also may include an integrated circuit die packaged within the communication chip 706. In accordance with some such example embodiments, the integrated circuit die of the communication chip includes one or more semiconductor devices as variously described herein. As will be appreciated in light of this disclosure, note that multi-standard wireless capability may be integrated directly into the processor 704 (e.g., where functionality of any chips 706 is integrated into processor 704, rather than having separate communication chips). Further note that processor 704 may be a chip set having such wireless capability. In short, any number of processor 704 and/or communication chips 706 can be used. Likewise, any one chip or chip set can have multiple functions integrated therein.

In various implementations, the computing system 700 may be a laptop, a netbook, a notebook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, or any other electronic device that processes data or employs one or more integrated circuit structures or devices formed using the disclosed techniques, as variously described herein.

It will be appreciated that in some embodiments, the various components of the computing system 700 may be combined or integrated in a system-on-a-chip (SoC) architecture. In some embodiments, the components may be hardware components, firmware components, software components or any suitable combination of hardware, firmware or software.

### FURTHER EXAMPLE EMBODIMENTS

The following examples pertain to further embodiments, from which numerous permutations and configurations will be apparent.

Example 1 is an integrated circuit that includes a first semiconductor device having a first semiconductor region extending in a first direction between a first source region and a first drain region, and a first gate structure extending in a second direction over the first semiconductor region. The integrated circuit also includes a second semiconductor device having a second semiconductor region extending in the first direction between a second source region and a second drain region, and a second gate structure extending in the second direction over the second semiconductor region. The first gate structure has a first width along the first direction and the second gate structure has a second width along the first direction that is greater than the first width. The first gate structure includes a first conductive layer and a first conductive fill on the first conductive layer where the first conductive layer extends above the first semiconductor region to a first height. The second gate structure includes a second conductive layer and a second conductive fill on the second conductive layer where the second conductive layer extends above the second semiconductor region to a second height that is within 2 nm of the first height.

Example 2 includes the integrated circuit of Example 1, wherein the first semiconductor region comprises a plurality of first semiconductor nanoribbons and the second semiconductor region comprises a plurality of second semiconductor nanoribbons.

Example 3 includes the integrated circuit of Example 2, wherein the plurality of first semiconductor nanoribbons and the plurality of second semiconductor nanoribbons comprise germanium, silicon, or a combination thereof.

Example 4 includes the integrated circuit of any one of Examples 1-3, wherein the first gate structure includes a first gate dielectric around the first semiconductor region, and the second gate structure includes a second gate dielectric around the second semiconductor region.

Example 5 includes the integrated circuit of Example 4, wherein the first gate dielectric is directly between the first semiconductor region and the first conductive layer, and the second gate dielectric is directly between the second semiconductor region and the second conductive layer.

Example 6 includes the integrated circuit of any one of Examples 1-5, wherein the first conductive layer and the second conductive layer comprise titanium or tungsten.

Example 7 includes the integrated circuit of any one of Examples 1-6, wherein the second height is within 1 nm of the first height.

Example 8 includes the integrated circuit of any one of Examples 1-7, wherein the second width is at least 1.5 times greater than the first width.

Example 9 includes the integrated circuit of any one of Examples 1-8, wherein the second width is at least two times greater than the first width.

Example 10 is a printed circuit board comprising the integrated circuit of any one of Examples 1-9.

Example 11 is an electronic device that includes a chip package comprising one or more dies. At least one of the one or more dies includes a first semiconductor device having a first semiconductor region extending in a first direction between a first source region and a first drain region, and a first gate structure extending in a second direction over the first semiconductor region. The integrated circuit also includes a second semiconductor device having a second semiconductor region extending in the first direction between a second source region and a second drain region, and a second gate structure extending in the second direction over the second semiconductor region. The first gate structure has a first width along the first direction and the second gate structure has a second width along the first direction that is greater than the first width. The first gate structure includes a first conductive layer and a first conductive fill on the first conductive layer where the first conductive layer extends above the first semiconductor region to a first height. The second gate structure includes a second conductive layer and a second conductive fill on the second conductive layer where the second conductive layer extends above the second semiconductor region to a second height that is substantially the same as the first height. According to one such example, the first height is within 1 nm of the second height. In another such example, the uppermost surfaces of the first conductive layer and the second conductive layer are within 1 nm of a same imaginary horizontal line.

Example 12 includes the electronic device of Example 11, wherein the first semiconductor region comprises a plurality of first semiconductor nanoribbons and the second semiconductor region comprises a plurality of second semiconductor nanoribbons.

Example 13 includes the electronic device of Example 12, wherein the plurality of first semiconductor nanoribbons and the plurality of second semiconductor nanoribbons comprise germanium, silicon, or a combination thereof.

Example 14 includes the electronic device of any one of Examples 11-13, wherein the first gate structure includes a first gate dielectric around the first semiconductor region, and the second gate structure includes a second gate dielectric around the second semiconductor region.

Example 15 includes the electronic device of Example 14, wherein the first gate dielectric is directly between the first semiconductor region and the first conductive layer, and the second gate dielectric is directly between the second semiconductor region and the second conductive layer.

Example 16 includes the electronic device of any one of Examples 11-15, wherein the first conductive layer and the second conductive layer comprise titanium or tungsten.

Example 17 includes the electronic device of any one of Examples 11-16, wherein the second height is within 1 nm of the first height.

Example 18 includes the electronic device of any one of Examples 11-17, wherein the second width is at least 1.5 times greater than the first width.

Example 19 includes the electronic device of any one of Examples 11-18, wherein the second width is at least two times greater than the first width.

Example 20 includes the electronic device of any one of Examples 11-19, further comprising a printed circuit board, wherein the chip package is coupled to the printed circuit board.

Example 21 is a method of forming an integrated circuit. The method includes forming a first fin comprising first semiconductor material, the first fin extending above a substrate and extending in a first direction; forming a second fin comprising second semiconductor material, the second fin extending above a substrate and extending in the first direction; forming a first sacrificial layer extending over the first semiconductor material in a second direction different from the first direction, the first sacrificial layer having a first width in the first direction; forming first spacer structures on sidewalls of the first sacrificial layer; forming a second sacrificial layer extending over the second semiconductor material in the second direction, the second sacrificial layer having a second width in the first direction that is greater than the first width; forming second spacer structures on sidewalls of the second sacrificial layer; removing both the first sacrificial layer and the second sacrificial layer to reveal a first trench having the first width between the first spacer structures and a second trench having the second width between the second spacer structures; forming a first conductive layer over the first semiconductor material and over sidewalls of the first spacer structures within the first trench; forming a second conductive layer over the second semiconductor material and over sidewalls of the second spacer structures within the second trench; forming a sacrificial material within the first trench and within the second trench over the first conductive layer and the second conductive layer; polishing a top surface of the sacrificial material using chemical mechanical polishing (CMP); recessing the sacrificial material within each of the first trench and the second trench, such that a recessed portion of the sacrificial material within the first trench has substantially the same height above the first semiconductor material as a recessed portion of the sacrificial material within the second trench above the second semiconductor material; and removing an exposed portion of the first conductive layer above the recessed portion of the sacrificial material within the first trench, and removing an exposed portion of the second conductive layer above the recessed portion of the sacrificial material within the second trench. According to some such examples, the uppermost surface of the recessed portion of the sacrificial material within the first trench and the uppermost surface of the recessed portion of the sacrificial material within the second trench are within 1 nm of a same imaginary horizontal line.

Example 22 includes the method of Example 21, wherein polishing the top surface of the sacrificial material using CMP comprises polishing the top surface of the sacrificial material until the top surface of the sacrificial material over the first trench and the second trench is substantially coplanar with a top surface of the first conductive layer and the second conductive layer outside of the first trench and the second trench. In one such example, the height variation between two surfaces that are substantially coplanar may be less than 1 nm, because they are polished together.

Example 23 includes the method of Example 21 or 22, wherein the sacrificial material is a carbon hard mask (CHM).

Example 24 includes the method of any one of Examples 21-23, wherein polishing the top surface of the sacrificial material using CMP comprises polishing the top surface of the sacrificial material with a slurry that comprises silica.

Example 25 includes the method of any one of Examples 21-24, wherein the first conductive layer and the second conductive layer each comprises titanium or tungsten.

Example 26 includes the method of any one of Examples 21-25, wherein the second width is at least 1.5 times greater than the first width.

Example 27 includes the method of any one of Examples 21-26, wherein the second width is at least two times greater than the first width.

Example 28 is a method of forming an integrated circuit. The method includes forming a first group of fins comprising semiconductor material, the first group of fins extending above a substrate and extending parallel to each other in a first direction, the first group of fins having a first fin density; forming a second group of fins comprising semiconductor material, the second group of fins extending above the substrate and extending parallel to each other in the first direction, the second group of fins having a second fin density lower than the first fin density; forming a sacrificial material over the first group of fins and the second group of fins; polishing a top surface of the sacrificial material using chemical mechanical polishing (CMP) until a top surface of the first group of fins and the second group of fins is exposed; and forming a layer of the sacrificial material on the polished top surface of the sacrificial material.

Example 29 includes the method of Example 28, further including forming a masking layer over the layer of sacrificial material; forming a recess extending through the masking layer, through the layer of sacrificial material, and through the sacrificial material, thus exposing one or more fins; and removing the exposed one or more fins.

Example 30 includes the method of Example 28 or 29, wherein the sacrificial material is a carbon hard mask (CHM).

Example 31 includes the method of any one of Examples 28-30, wherein polishing the top surface of the sacrificial material using CMP comprises polishing the top surface of the sacrificial material with a slurry that comprises silica.

Example 32 is a method of forming an integrated circuit. The method includes forming a grating on an underlying structure, the grating comprising backbone features, each backbone feature sandwiched between a pair of spacers, the grating including a first group of backbone features having a first pitch and a second group of backbone features including a second pitch smaller than the first pitch; forming a sacrificial material over the first group of backbone features and the second group of backbone features; polishing a top surface of the sacrificial material using chemical mechanical polishing (CMP) until a top surface of the first group of backbone features and the second group of backbone features is exposed; removing the backbone features and the sacrificial material, thereby leaving a diverse-pitch pattern of spacers; and using the diverse-pitch pattern of spacers to form features in the underlying structure.

Example 33 includes the method of Example 32, wherein the sacrificial material is a carbon hard mask (CHM).

Example 34 includes the method of Example 32 or 33, wherein polishing the top surface of the sacrificial material using CMP comprises polishing the top surface of the sacrificial material with a slurry that comprises silica.

Example 35 includes the method of any one of Examples 32-34, wherein the spacers of the diverse-pitch pattern of spacers all have substantially a same height (e.g., within 2 nm of each other, or +/−1 nm of a target height).

The foregoing description of the embodiments of the disclosure has been presented for the purposes of illustration and description. It is not intended to be exhaustive or to limit the disclosure to the precise forms disclosed. Many modifications and variations are possible in light of this disclosure. It is intended that the scope of the disclosure be limited not by this detailed description, but rather by the claims appended hereto.

What is claimed is:

1. An integrated circuit comprising:
a first semiconductor device having a first semiconductor region extending in a first direction between a first source region and a first drain region, and a first gate structure extending in a second direction over the first semiconductor region, the first gate structure having a first width along the first direction; and
a second semiconductor device having a second semiconductor region extending in the first direction between a second source region and a second drain region, and a second gate structure extending in the second direction over the second semiconductor region, the second gate structure having a second width along the first direction, where the second width is greater than the first width;
wherein the first gate structure includes a first conductive layer and a first conductive fill on the first conductive layer, the first conductive layer extending above the first semiconductor region to a first height, and the second gate structure includes a second conductive layer and a second conductive fill on the second conductive layer, the second conductive layer extending above the second semiconductor region to a second height that is within 2 nm of the first height.

2. The integrated circuit of claim 1, wherein the first semiconductor region comprises a plurality of first semiconductor nanoribbons and the second semiconductor region comprises a plurality of second semiconductor nanoribbons.

3. The integrated circuit of claim 1, wherein the first gate structure includes a first gate dielectric around the first semiconductor region, and the second gate structure includes a second gate dielectric around the second semiconductor region.

4. The integrated circuit of claim 3, wherein the first gate dielectric is directly between the first semiconductor region and the first conductive layer, and the second gate dielectric is directly between the second semiconductor region and the second conductive layer.

5. The integrated circuit of claim 1, wherein the first conductive layer and the second conductive layer comprise titanium or tungsten.

6. The integrated circuit of claim 1, wherein the second width is at least two times greater than the first width.

7. A printed circuit board comprising the integrated circuit of claim 1.

8. An electronic device, comprising:
a chip package comprising one or more dies, at least one of the one or more dies comprising
a first semiconductor device having a first semiconductor region extending in a first direction between a first source region and a first drain region, and a first gate structure extending in a second direction over the first semiconductor region, the first gate structure having a first width along the first direction; and
a second semiconductor device having a second semiconductor region extending in the first direction between a second source region and a second drain region, and a second gate structure extending in the second direction over the second semiconductor region, the second gate structure having a second width along the first direction, where the second width is greater than the first width;
wherein the first gate structure includes a first conductive layer and a first conductive fill on the first conductive layer, the first conductive layer extending above the first semiconductor region to a first height, and the second gate structure includes a second conductive layer and a second conductive fill on the second conductive layer, the second conductive layer extending above the second semiconductor region to a second height that is substantially the same as the first height.

9. The electronic device of claim 8, wherein the first semiconductor region comprises a plurality of first semiconductor nanoribbons and the second semiconductor region comprises a plurality of second semiconductor nanoribbons.

10. The electronic device of claim 8, wherein the first gate structure includes a first gate dielectric around the first semiconductor region, and the second gate structure includes a second gate dielectric around the second semiconductor region.

11. The electronic device of claim 8, wherein the first conductive layer and the second conductive layer comprise titanium or tungsten.

12. The electronic device of claim 8, wherein the second width is at least two times greater than the first width.

13. The electronic device of claim 8, further comprising a printed circuit board, wherein the chip package is coupled to the printed circuit board.

14. A method of forming an integrated circuit, comprising:
forming a first fin comprising first semiconductor material, the first fin extending above a substrate and extending in a first direction;
forming a second fin comprising second semiconductor material, the second fin extending above a substrate and extending in the first direction;
forming a first sacrificial layer extending over the first semiconductor material in a second direction different from the first direction, the first sacrificial layer having a first width in the first direction;
forming first spacer structures on sidewalls of the first sacrificial layer;
forming a second sacrificial layer extending over the second semiconductor material in the second direction, the second sacrificial layer having a second width in the first direction that is greater than the first width;
forming second spacer structures on sidewalls of the second sacrificial layer;
removing both the first sacrificial layer and the second sacrificial layer to reveal a first trench having the first width between the first spacer structures and a second trench having the second width between the second spacer structures;
forming a first conductive layer over the first semiconductor material and over sidewalls of the first spacer structures within the first trench;
forming a second conductive layer over the second semiconductor material and over sidewalls of the second spacer structures within the second trench;
forming a sacrificial material within the first trench and within the second trench over the first conductive layer and the second conductive layer;
polishing a top surface of the sacrificial material using chemical mechanical polishing (CMP);
recessing the sacrificial material within each of the first trench and the second trench, such that a recessed portion of the sacrificial material within the first trench has substantially the same height above the first semiconductor material as a recessed portion of the sacrificial material within the second trench above the second semiconductor material; and
removing an exposed portion of the first conductive layer above the recessed portion of the sacrificial material within the first trench, and removing an exposed portion of the second conductive layer above the recessed portion of the sacrificial material within the second trench.

15. The method of claim 14, wherein polishing the top surface of the sacrificial material using CMP comprises polishing the top surface of the sacrificial material until the top surface of the sacrificial material over the first trench and the second trench is substantially coplanar with a top surface of the first conductive layer and the second conductive layer outside of the first trench and the second trench.

16. The method of claim 14, wherein the sacrificial material is a carbon hard mask (CHM).

17. The method of claim 16, wherein polishing the top surface of the sacrificial material using CMP comprises polishing the top surface of the sacrificial material with a slurry that comprises silica.

18. The method of claim 14, wherein the first conductive layer and the second conductive layer each comprises titanium or tungsten.

19. The method of claim 14, wherein the second width is at least 1.5 times greater than the first width.

20. The method of claim 14, wherein the second width is at least two times greater than the first width.
